(19) United States
(12) Patent Application Publication
(10) Pub. No.: US 2026/0149156 A1
(43) Pub. Date: May 28, 2026

(54) AIR CAVITY AND CERAMIC WAVEGUIDE (CWG) RESONATOR MIXED FILTER SOLUTION

(71) Applicant: Telefonaktiebolaget LM Ericsson (publ), Stockholm (SE)

(72) Inventors: Chunyun JIAN, Ottawa (CA); Mi ZHOU, Nepean (CA); Zhen Hong WANG, Stittsville (CA); Yuan SUN, Stittsville (CA)

(21) Appl. No.: 19/121,488

(22) PCT Filed: Oct. 17, 2022
(86) PCT No.: PCT/IB2022/059952

§ 371 Date: Apr. 16, 2025

(51) Int. Cl. H01P 1/207; H05K 5/02

(52) U.S. Cl. CPC H01P 1/207; H05K 5/0217

(57) ABSTRACT

Air cavity and ceramic waveguide resonator mixed filter solutions are disclosed. According to one aspect, a combined filter assembly includes an air cavity filter coupled to a ceramic waveguide (CWG) filter. The CWG filter exhibits a wall that presses against a rigid plate. Between the rigid plate and a wall of the air cavity filter is a compressible conductive gasket that is compressed between the wall of the air cavity filter and the rigid plate. The air cavity filter and the CWG filter are secured to a support base. The CWG filter is secured to the support base by flexible clamps that allow for thermal expansion of the CWG filter. The flexible clamps are secured to the support base by screws. The support base exhibits surfaces or walls that receive and anchor the screws.

### TECHNICAL FIELD

The present disclosure relates to wireless communications, and in particular, to air cavity and ceramic waveguide (CWG) resonator mixed filter solutions.

### BACKGROUND

In the field of wireless communications, a radio base station is configured to transmit radio frequency (RF) energy at high power to be received by wireless devices at various distances from the radio base station. High power RF transmission calls for RF filters that can handle high power.

An air cavity filter has a high Q and can handle high power. However, the air cavity filter is bulky, heavy and costly. A ceramic waveguide (CWG) filter is smaller and less costly than an air cavity filter, but has a lower Q and cannot handle high power without generating passive intermodulation (PIM) effects. Q is a measure of the ability of the filter to store energy without significant loss.

Since the power of RF transmission of a radio base station is much greater than the power in signals received at the radio base station from wireless devices, a known design involves combining an air cavity filter for transmission of high power signals with a CWG filter for reception of lower power signals.

There are challenges to design of a combined air cavity/CWG filter. For the combined filter design, the CWG filter must be attached and aligned to the air cavity filter in such a way that there is good coupling of electromagnetic waves between the two filters, minimal reflection and minimal leakage of electromagnetic waves at the boundary between the two filters.

At the boundary between the air cavity filter and the CWG filter, an area of exposed ceramic of the CWG filter body is exposed to the interior of the air cavity filter. To align the CWG filter and the air cavity filter, a rigid support base is provided to which both filters are attached. The support base may be made of a metal or may be a printed circuit board, for example. The air cavity filter may be soldered or screwed to the support base with minimal reliability concerns. However, using either soldering or screws to attach the CWG filter to the base give rise to significant reliability concerns.

The CWG filter is fragile and screws may damage the CWG filter body. Also, because of thermal mismatch between the CWG filter and the support base, a solder connection between the two may break. Although a small ceramic filter could be soldered onto a PCB without reliability issues, a ceramic filter of the size necessary for RF communications cannot be soldered to the support base or the metallic body of the air cavity filter without significant reliability issues due to thermal mismatch.

FIG. 1 shows a known combined filter design having an air cavity filter 2 and a CWG filter 4 secured to a support base 6. A problem with this design is that the support base 6 is large, bulky and costly. A fastening screw 8 is used to drive an end wall of the CWG filter 2 against a wall of the air cavity filter 2. But the fastening screw 8 may wear over time and fail to provide sufficient force to maintain a good connection between the CWG filter 4 and the air cavity filter 2. Thus, PIM and electromagnetic leakage may occur at the interface 10 between the two filters. The interface 10 is where an end wall of the CWG filter 4 meets the facing wall of the air cavity filter 2. Clamps 12 are screwed to the support base 6 to secure the CWG filter 4 in the vertical direction, but this may cause the CWG filter 4 to be unstable as heating causes the CWG filter 4 to expand and shrink and the clamps 12 may not make contact with the CWG filter 4 during the temperature cycling.

### SUMMARY

Some embodiments advantageously provide air cavity and ceramic waveguide resonator mixed filter solutions.

According to one aspect, a combined filter apparatus is provided. The combined filter apparatus includes an air cavity filter having a window in a first wall of the air cavity filter. A ceramic waveguide, CWG, filter, has a first region and a second region, the second region of the CWG filter is configured to be inserted into the window of the first wall of the air cavity filter. The first region has a first outer dimension that is greater than a second outer dimension of the second region to form a second wall at a boundary between the first region and the second region, the second wall facing a longitudinal direction of the CWG filter. The combined filter apparatus also includes aa rigid plate having a rigid plate inner dimension sized to enable the rigid plate to slide over the second region of the CWG filter and be pressed against the second wall of the CWG filter. A compressible conductive gasket having a gasket inner dimension greater than or equal to the rigid plate inner dimension is configured to slide over the second region of the CWG filter and be compressed between the first wall and the rigid plate when the second region of the CWG filter is inserted into the window of the first wall of the air cavity filter.

According to this aspect, in some embodiments, the combined filter apparatus includes incompressible pads configured between the rigid plate and the first wall of the air cavity filter to limit an amount of compression of the compressible conductive gasket. In some embodiments, the rigid plate has a rigid plate outer dimension that exceeds the first outer dimension of the first region of the CWG filter. In some embodiments, the compressible conductive gasket has a gasket outer dimension that is less than or equal to an outer dimension of the rigid plate. In some embodiments, the rigid plate is configured with a recess to receive the compressible conductive gasket. In some embodiments, the recess has a depth to enable the compressible conductive gasket to be hidden from view when compressed between the rigid plate and the first wall of the air cavity filter. In some embodiments, the combined filter apparatus further includes a support base configured to rigidly affix the CWG filter and the air cavity filter when the second region of the CWG filter is inserted into the window. In some embodiments, the CWG filter is configured to be affixed to the support base by at least one clamp that is flexible to allow for thermal expansion of the CWG filter over the affixed surface of the support base. In some embodiments, the at least one clamp includes a first slot and the support base includes a first hole aligned with the first slot, the at least one clamp being affixable to the support base by inserting an anchoring element into the first hole in the support base through the first slot in the clamp, the first slot enabling adjustment of a position of the clamp in a direction parallel to a direction of the first slot. In some embodiments, the CWG filter has a rectangular cross-section and a broad wall and the at least one clamp is affixable to a surface of the support base that is parallel with the broad wall of the CWG filter. In some embodiments, the CWG filter has a rectangular cross-section and a narrow wall and the at least one clamp is affixable to a surface of the support base that is parallel to the narrow wall of the CWG filter. In some embodiments, the combined filter apparatus also includes a spring stopper configured to be affixed to the support base and to provide spring-force to the CWG filter in the longitudinal direction of the CWG filter toward the first wall of the air cavity filter to maintain compression of the compressible conductive gasket between the rigid plate and the first wall. In some embodiments, the spring stopper includes a second slot and the support base includes a second hole and the spring stopper is affixable to the support base by inserting an anchoring element into the second hole in the support base through the second slot in the spring stopper, the second slot enabling adjustment of an amount of compression of the compressible conductive gasket. In some embodiments, the rigid plate includes flexible fingers configured to flex under pressure to flatten a curvature of the flexible fingers when compression is applied to the rigid plate. In some embodiments, the filter apparatus includes a compressible conductive gasket configured to fit over the second region of the CWG filter to be compressed between the rigid plate and the first wall of the air cavity filter. In some embodiments, the rigid plate includes a recess configured to receive the compressible conductive gasket, the compressible conductive gasket having an uncompressed thickness that is greater than a height of the recess. In some embodiments, the rigid plate, is configurable to be soldered to the CWG filter. According to another aspect, a filter assembly includes a support base, an air cavity filter and a ceramic waveguide (CWG) filter. The air cavity filter has a first window in a first wall of the air cavity filter. The CWG filter has a first cross section in a first region of the CWG filter and has a second cross section in a second region of the CWG filter, the second region of the CWG filter being inserted into the window of the first wall of the air cavity filter. A difference between the first and second cross sections forms a second wall of the CWG filter at a boundary between the first and second regions of the CWG filter. The second region of the CWG filter is inserted into the first window of the first wall of the air cavity filter. A flexible clamp securing the CWG filter to the support base is provided. The flexible clamp is flexible to allow for thermal expansion of the CWG filter. A rigid plate having a second window through which the second region of the CWG filter passes has a first surface pressed against the second wall of the CWG filter. A compressible conductive gasket is compressed between the rigid plate and the first wall of the air cavity filter by a spring-force. A spring stopper secured to the support base makes contact with an end wall of the CWG filter. The spring stopper has a spring element supplying the spring-force to compress the compressible conductive gasket to electromagnetically seal a junction between the CWG filter and the air cavity filter and to prevent relative movement between the CWG filter and the air cavity filter along the longitudinal axis of the CWG filter.

According to this aspect, in some embodiments, the rigid plate has a recess and the compressible conductive gasket is positioned within the recess. In some embodiments, the filter assembly also includes rigid pads between the rigid plate and the first wall and making contact with the rigid plate and the first wall of the air cavity filter to limit an amount by which the compressible conductive gasket is compressed. In some embodiments, at least one of the first and second cross sections is rectangular. In some embodiments, the rigid plate has a first face, the first face having an area that is greater than an area of the second wall of the CWG filter. In some embodiments, the rigid plate has a second face and the compressible gasket has a third face, the second face of the rigid plate having an area that is greater than an area of the third face of the compressible conductive gasket. In some embodiments, the flexible clamp includes a first slot and is secured to the support base by a first anchoring element inserted through the first slot of the flexible clamp, the first slot of the flexible clamp enabling adjustment of an amount of compressible force applied to the CWG filter by the flexible clamp. In some embodiments, the spring stopper includes a second slot and is secured to the support base by a second anchoring element inserted through the second slot of the spring stopper, the second slot of the spring stopper enabling adjustment of an amount of the spring-force applied to the CWG filter. In some embodiments, the rigid plate includes flexible fingers configured to flex under pressure to flatten a curvature of the flexible fingers when compression is applied to the rigid plate. In some embodiments, the filter assembly includes a compressible conductive gasket configured to fit over the second region of the CWG filter to be compressed between the rigid plate and the first wall of the air cavity filter. In some embodiments, the rigid plate includes a recess configured to receive the compressible conductive gasket, the compressible conductive gasket having an uncompressed thickness that is greater than a height of the recess. In some embodiments, the rigid plate, is configurable to be soldered to the CWG filter.

### BRIEF DESCRIPTION OF THE DRAWINGS

A more complete understanding of the present embodiments, and the attendant advantages and features thereof, will be more readily understood by reference to the following detailed description when considered in conjunction with the accompanying drawings wherein:

FIG. 1 is a known design of a combined CWG/air cavity filter;

FIG. 2 is an example of a CWG filter designed to exhibit a wall facing a longitudinal direction of the CWG filter according to principles set forth herein;

FIG. 3 is an example of a CWG filter with a rigid plate placed against a wall of the CWG filter according to principles set forth herein;

FIG. 4 is an example of a CWG filter with a conductive gasket placed against the rigid plate that is placed against the wall of the CWG filter according to principles set forth herein;

FIG. 5 is an example of the conductive gasket against the rigid plate according to principles set forth herein;

FIG. 6 is a side view of one example of the conductive gasket against the rigid plate according to principles set forth herein;

FIG. 7 is another example of the rigid plate having a recess configured to receive the conductive gasket according to principles set forth herein;

FIG. 8 is a side view of the rigid plate and the conductive gasket received by the recess of the rigid plate according to principles set forth herein;

FIG. 9 is an example of a combined CWG/air cavity filter constructed according to principles set forth herein;

FIG. 10 is an end view of the example of FIG. 9;

FIG. 11 is a top view of the example of FIG. 9;

FIG. 12 is a side view of the example of FIG. 9;

FIG. 13 is another example of a combined CWG/air cavity filter constructed according to principles set forth herein;

FIG. 14 is an end view of the example of FIG. 13;

FIG. 15 is a top view of the example of FIG. 13;

FIG. 16 is a side view of the example of FIG. 13;

FIG. 17 is an example of a rigid plate that has protrusions that flex under applied force according to principles set forth herein;

FIG. 18 illustrates an embodiment of the rigid plate with flexible protrusions along with a gasket; and

FIG. 19 illustrates an embodiment where the rigid plate with flexible protrusions has a recess to receive the gasket shown in FIG. 18.

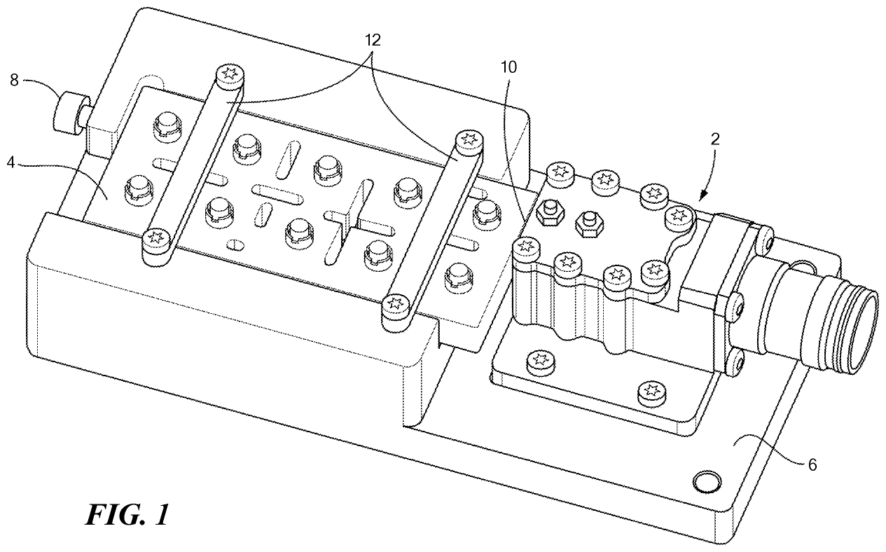

### DETAILED DESCRIPTION

Before describing in detail exemplary embodiments, it is noted that the embodiments reside primarily in combinations of components related to air cavity and ceramic waveguide resonator mixed filter solutions. Accordingly, components have been represented where appropriate by conventional symbols in the drawings, showing only those specific details that are pertinent to understanding the embodiments so as not to obscure the disclosure with details that will be readily apparent to those of ordinary skill in the art having the benefit of the description herein.

As used herein, relational terms, such as “first” and “second,” “top” and “bottom,” and the like, may be used solely to distinguish one entity or element from another entity or element without necessarily requiring or implying any physical or logical relationship or order between such entities or elements. The terminology used herein is for the purpose of describing particular embodiments only and is not intended to be limiting of the concepts described herein. As used herein, the singular forms “a”, “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

In embodiments described herein, the joining term, “in communication with” and the like, may be used to indicate electrical or data communication, which may be accomplished by physical contact, induction, electromagnetic radiation, radio signaling, infrared signaling or optical signaling, for example. One having ordinary skill in the art will appreciate that multiple components may interoperate and modifications and variations are possible of achieving the electrical and data communication.

In some embodiments described herein, the term “coupled,” “connected,” and the like, may be used herein to indicate a connection, although not necessarily directly, and may include wired and/or wireless connections.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

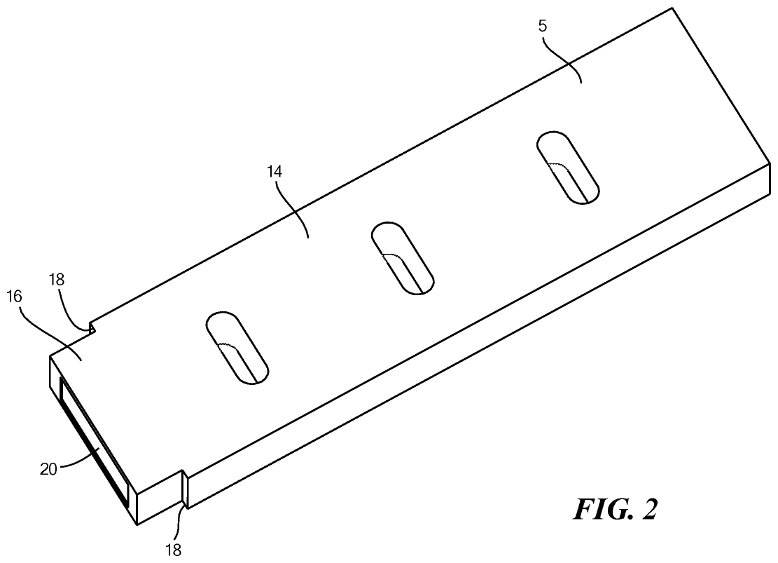

Some embodiments are directed to air cavity and ceramic waveguide resonator mixed filter solutions. Referring again to the drawing figures, there is shown in FIG. 2 a CWG filter 5 modified to have two different cross sections. A first region 14 of the CWG filter 5 has a larger cross sectional area than a second region 16 of the of the CWG filter 5. The difference between these two cross sectional areas creates a wall 18 (or shoulder) on either side of the body of the CWG filter 5. The wall 18 faces in a same direction as an open face 20 of the CWG filter 5. The open face 20 of the CWG filter 5 faces and couples to a window of the air cavity filter 2.

FIG. 3 shows the CWG filter 5 with a rigid plate 22. The rigid plate 22 is configured to slide over the second region 16 of the CWG filter 5 and be pressed against the wall 18 of the CWG filter 5. In some embodiments, the rigid plate 22 has affixed thereon one or more pads 24. The rigid plate 22 may be soldered to the CWG filter 5.

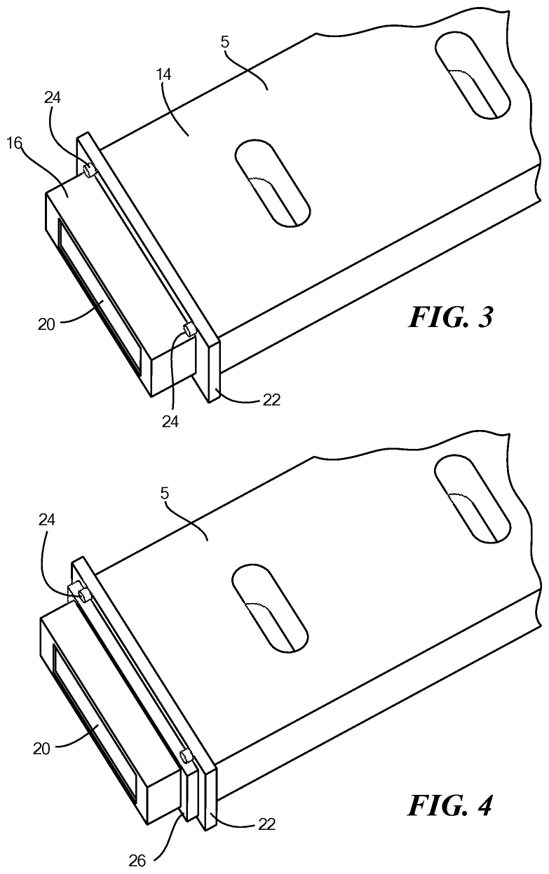

FIG. 4 shows the CWG filter 5 with rigid plate 22 and pads 24. In addition, a compressible conductive gasket 26 is configured to slide over the second region 16 of the CWG filter 5 and be pressed against the rigid plate 22. The conductive gasket 26 may be a compressible material that has an outer surface that is electrically conductive. The conductive gasket 26 is configured to compress when the CWG filter 5 is moved in a longitudinal direction toward the air cavity filter 2 to press the conductive gasket 26 against a wall of the air cavity filter 2. By compressing the conductive gasket between a face of the rigid plate 22 and a wall of the air cavity filter 2, leakage of electromagnetic waves at the interface between the CWG filter 5 and the air cavity filter 2 may be minimized or substantially eliminated. In some embodiments, the pads 24 are not as thick as a thickness of the conductive gasket so that the pads 24 prevent the conductive gasket 26 from being compressed beyond a certain amount of compression. In such embodiments, the conductive gasket 26 may be compressed up to the point that the pads 24 make contact with the wall of the air cavity filter 2. The pads 24 may be made of the same material as the rigid plate 22. In some embodiments, the pads 24 are not present.

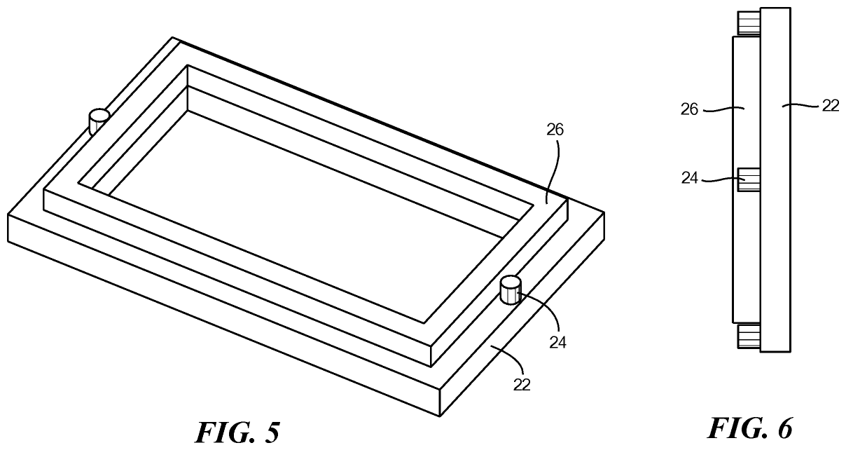

FIG. 5 is a perspective view of the rigid plate 22, pads 24 and conductive gasket 26. Note that although two pads 24 are shown in FIG. 5, in some embodiments there may be only one pad or more than two pads 24 or no pads at all. Although the pads are shown as being circularly cylindrical, the pads may be elongated in a direction parallel to a perimeter of the conductive gasket 26. In FIG. 5, the conductive gasket 26 has an outer dimension that is less than the corresponding outer dimension of the rigid plate 22. In some embodiments, the outer dimension of the conductive gasket 26 may be equal to or greater than the corresponding outer dimension of the rigid plate 22.

FIG. 6 is a side view of the rigid plate 22, pads 24 and conductive gasket 26. Note that the particular positions of the pads 24 around the perimeter of the conductive gasket may be different in different embodiments. As shown in FIG. 6, the pads 24 have a thickness that is less than the thickness of the conductive gasket 26. This allows for compression of the conductive gasket 26 until the pads 24 make contact with the face of the rigid plate 22.

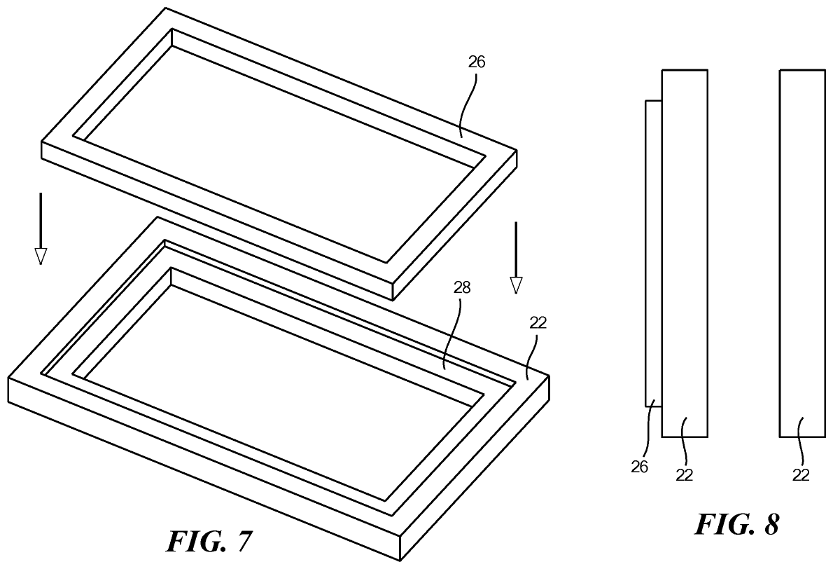

FIG. 7 is an example of an embodiment of the rigid plate 22 having a recess 28 around the inner perimeter of the rigid plate 22. The recess 28 of the rigid plate 22 is configured to receive the conductive gasket 26 and the conductive gasket 26 has an outer dimension configured to be received by the recess 28.

FIG. 8 is a side view the conductive gasket 26 placed in the recess 29 before compression (on the left of FIG. 8) and after compression (on the right of FIG. 8). Thus, before compression, the conductive gasket 26 has a height that is greater than the depth of the recess 28. In some embodiments, a dielectric sheet such as Kapton or a dielectric tape may be positioned in between the conductive gasket 26 and the wall of the air cavity filter. In some embodiments, when compressed, the conductive gasket 26 may be hidden from view. In some embodiments, the conductive gasket may have a height after compression that is greater than the depth of the recess 28.

Note that although the inner perimeters of both the rigid plate 22 and the conductive gasket 26 are shown as rectangles, in some embodiments these perimeters may have other shapes such for example, a circle. Also, the outer perimeters of the rigid plate 22 and/or the conductive gasket 26 need not be rectangles.

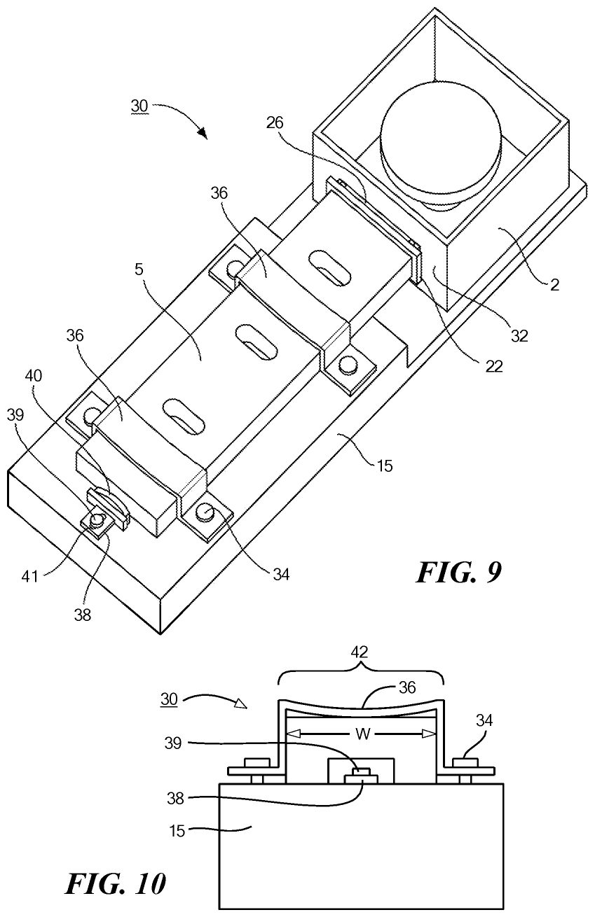

FIG. 9 is a perspective view of one example of a combined CWG/air cavity filter 30 which includes a redesigned support base 15, the CWG filter 5 and the air cavity filter 2. The support base 15 is made of a rigid material and has a width that is greater than a width of the CWG filter 5. The second region 16 of the CWG filter 5 is inserted through a window in a wall 32 of the air cavity filter 2. The conductive gasket 26 is positioned and compressed between the rigid plate 22 and wall 32 of the air cavity filter 2. The support base 15 is configured to receive fastening screws 34 to secure a pair of flexible clamps 36 to the support base 15. In some embodiments, there may be only one flexible clamp 36 that is secured to the support base 15 by two or more fastening screws 34. In some embodiments, there may be more than two flexible clamps 36 that are secured to the support base 15 by two or more fastening screws 34. The flexible clamps 36 serve to constrain vertical motion of the CWG filter 5 while allowing some thermal expansion of the CWG filter 5. To constrain horizontal motion of the CWG filter, a spring stopper having a stopper 38 and a spring 40 provides force in the horizonal direction. This spring-force firmly presses the wall 18 of the CWG filter 5 against the rigid plate 22, which compresses the conductive gasket 26 against the wall 32 of the air cavity filter 2. The stopper 38 is secured in position by a fastening screw 39 through a slot 41 in the body of the stopper 38. This provides control over an amount of spring-force applied to the CWG filter 5. The rigid plate 22 may be soldered to the CWG filter 5.

FIG. 10 is an end view of the combined CWG/air cavity filter 30 which shows that the flexible clamp 36 may have a concave region 42. The flexible clamp 36 may be made of plastic or metal so that the concave region 42 is configured to flex and allow thermal expansion of the CWG filter 5, at least to some extent, while constraining vertical displacement of the CWG filter 5. As shown in FIG. 10, the flexible clamp 36 has a width W that may be slightly larger than the width of the CWG filter 5.

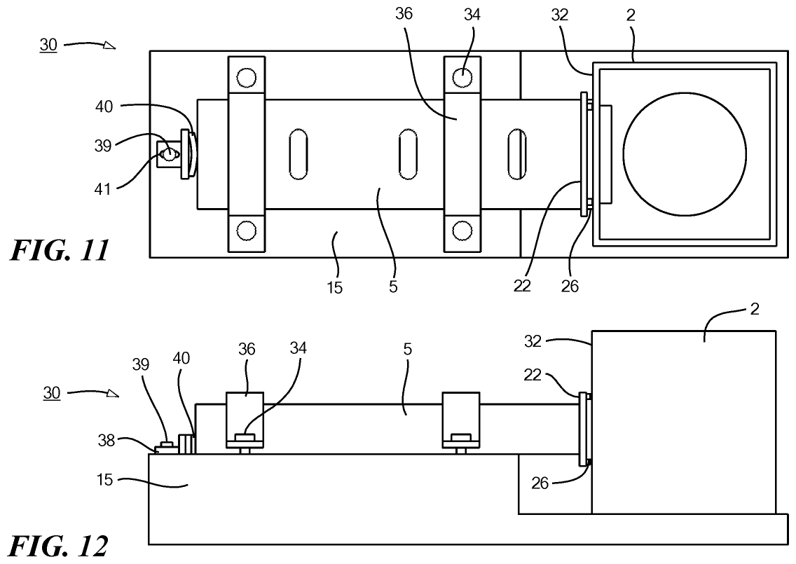

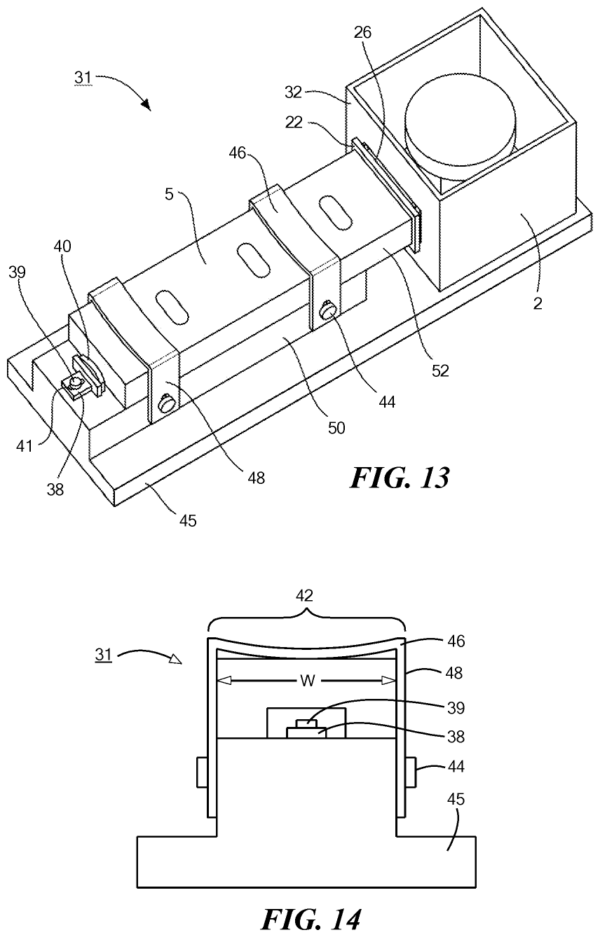

FIG. 11 is a top view of the combined CWG/air cavity filter 30 and FIG. 12 is a side view of the combined CWG/air cavity filter 30. In FIG. 11, an end of the second region 16 of the CWG filter 5 extends through the wall 32 into the interior of the air cavity filter 2. In some embodiments, the end of the second region 16 is flush with an interior side of the wall 32 of the air cavity filter 2.

FIG. 13 is a perspective view of another example of a combined CWG/air cavity filter 31 with fastening screws 44 received by a support base 45 to secure flexible clamps 46 to the support base 45. The support base 45 shown in FIG. 13 differs from the support base 15 shown in FIG. 9. In FIG. 9, the flexible clamps 36 have horizontal tabs that are flush to a surface of the support base 15 that faces the CWG filter 5. The fastening screws 44 that secure the flexible clamps 46 to the support base 15 are directed vertically downward. In FIG. 13, the flexible clamps 46 have vertical sides 48 that are flush with vertical wall 50 of the support base 45 and that are flush with the vertical side walls 52 of the CWG filter 5. In the embodiment of FIG. 13, The fastening screws 44 are directed horizontally.

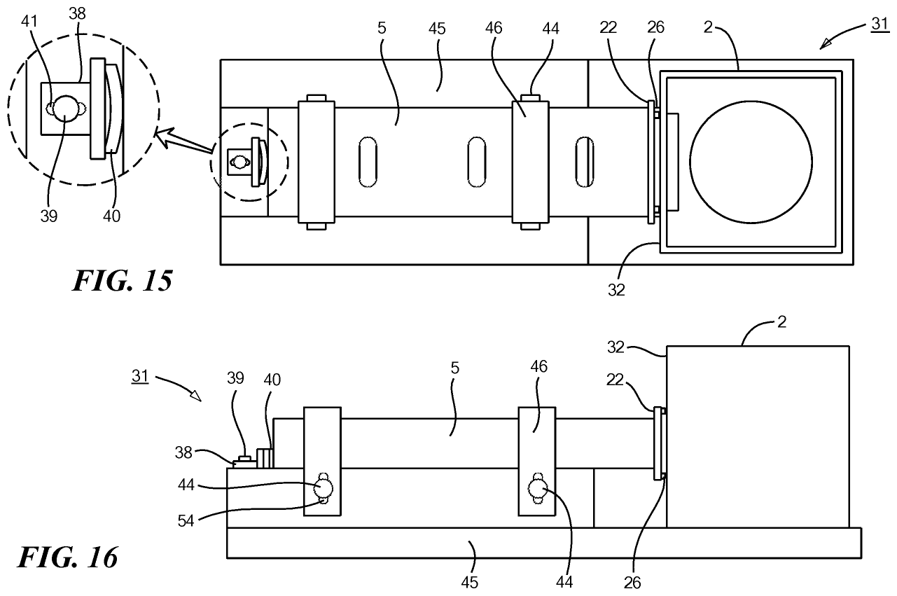

FIG. 14 is an end view of the combined CWG/air cavity filter 31 with the flexible clamps 46 that restrict vertical movement of the CWG filter 5 while allowing for thermal expansion (by virtue of the flexible concave region 42 of the flexible clamp 46). In this embodiment, a width between vertical walls 50 of the support base 45 is equal to a width between vertical sides walls 52 of the CWG filter 5. FIG. 15 is a top view of the combined CWG/air cavity filter 31 with a more detailed view of the stopper 38 and the spring 40, which shows that the fastening screw 39 is set in the slot 41 to allow for adjustment of the stopper position in the longitudinal direction of the CWG filter 5. As shown in FIG. 14, the flexible clamp 46 has a width W that may be slightly larger than the width of the CWG filter 5.

FIG. 16 is a side view of the combined CWG/air cavity filter 31. FIG. 16 shows that slots 54 in the vertical sides 48 of the flexible clamps 46 receive the fastening screws 44 and enable vertical adjustment of the flexible clamps 46.

Note that in FIGS. 9-16, the conductive gasket 26 is exposed to view. However, if the embodiment of the rigid plate 22 shown in FIGS. 7 and 8 are used, the conductive gasket 26 may be hidden from view. In some embodiments, the vertical walls 50 of the support base 45 may be replaced by walls exhibiting finite curvature and the flexible clamps 46 may exhibit matching curvature. Note further that the embodiment of the combined CWG/air cavity filter 30 shown in FIGS. 9-12 may be used when physical access to horizontally-directed fastening screws 44 would be difficult for a given installation, whereas the embodiment of the combined CWG/air cavity filter 31 shown in FIGS. 13-16 may be used when physical access to vertically-directed fastening screws 34 would be difficult for a given installation.

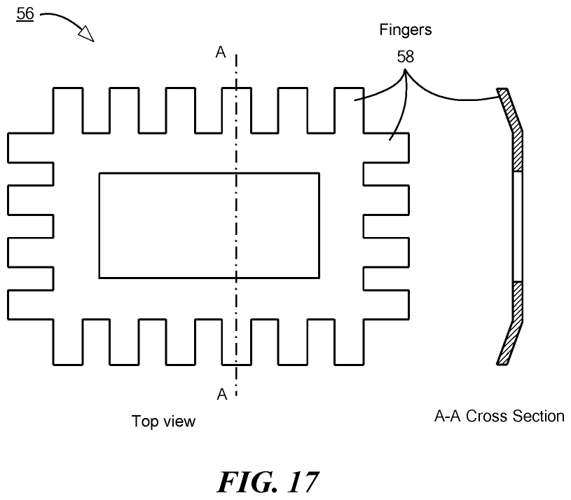

FIG. 17 shows a rigid plate 56 which may be employed instead of the rigid plate 22 in the configurations of FIGS. 3-16. The rigid plate 56 may be metallic and has flexible fingers 58 that may exhibit curvature. When the wall 18 of the CWG filter 5 is pressed against the rigid plate 56, the flexible fingers 58 of the rigid plate 56 may be flattened against the wall 32 of the air cavity filter 2. Then, the rigid plate 56 exhibits a spring like force against the wall of the air cavity filter 2. The rigid plate 56 may be soldered to the CWG filter 5.

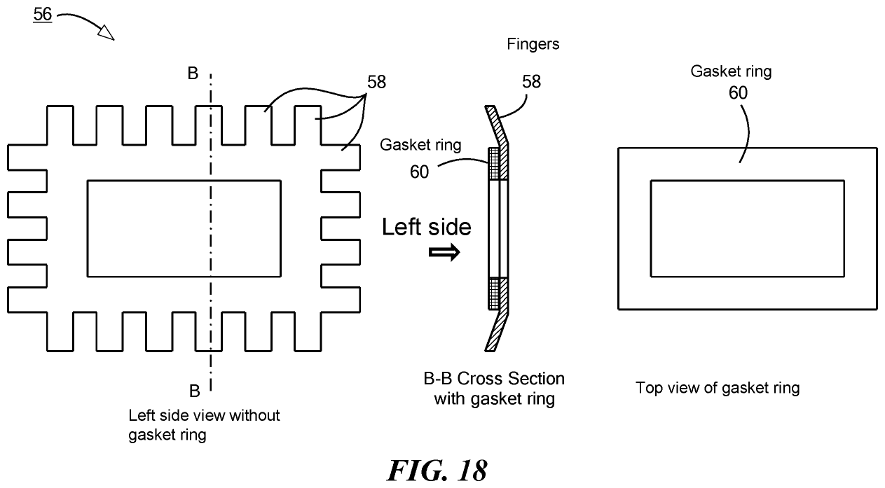

FIG. 18 illustrates the rigid plate 56 with a compressible conductive gasket 60 that may be positioned between the rigid plate 56 and the wall 32 of the air cavity filter 2 to reduce and/or substantially eliminate electromagnetic leakage at the interface between the CWG filter 5 and the air cavity filter 2. The rigid plate 56 may be soldered to the CWG filter 5.

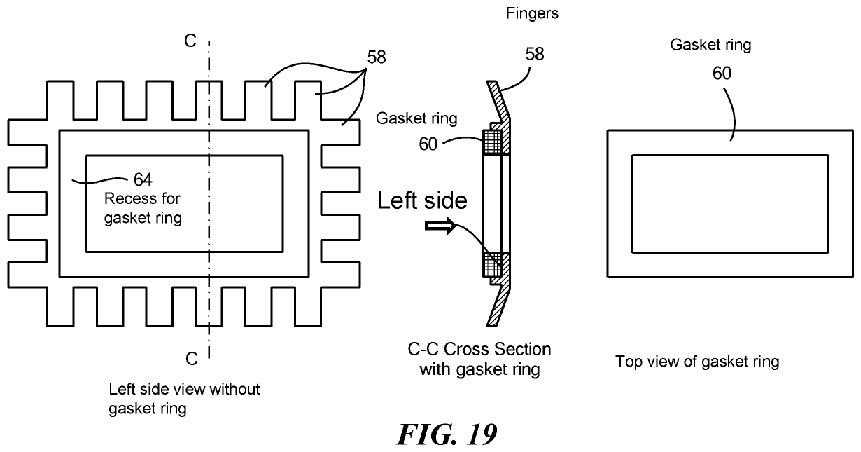

FIG. 19 illustrates the rigid plate 56 with a recess 64 configured to receive the compressible conductive gasket 60. The compressible conductive gasket 60 has a thickness that is greater than the height of the recess 64 so that the compressible conductive gasket 60 may be compressed between the rigid plate 56 and the wall 32 of the air cavity filter 2 to reduce and/or substantially eliminate electromagnetic leakage at the interface between the CWG filter 5 and the air cavity filter 2. The rigid plate 56 may be soldered to the CWG filter 5.

Many different embodiments have been disclosed herein, in connection with the above description and the drawings. It will be understood that it would be unduly repetitious and obfuscating to literally describe and illustrate every combination and subcombination of these embodiments. Accordingly, all embodiments can be combined in any way and/or combination, and the present specification, including the drawings, shall be construed to constitute a complete written description of all combinations and subcombinations of the embodiments described herein, and of the manner and process of making and using them, and shall support claims to any such combination or subcombination.

It will be appreciated by persons skilled in the art that the embodiments described herein are not limited to what has been particularly shown and described herein above. In addition, unless mention was made above to the contrary, it should be noted that all of the accompanying drawings are not to scale. A variety of modifications and variations are possible in light of the above teachings without departing from the scope of the following claims.

1. A combined filter apparatus, comprising:
an air cavity filter having a window in a first wall of the air cavity filter;
a ceramic waveguide, CWG, filter, the CWG filter having a first region and a second region, the second region of the CWG filter being configured to be inserted into the window of the first wall of the air cavity filter, the first region having a first outer dimension that is greater than a second outer dimension of the second region to form a second wall at a boundary between the first region and the second region, the second wall facing a longitudinal direction of the CWG filter;
a rigid plate having a rigid plate inner dimension sized to enable the rigid plate to slide over the second region of the CWG filter and be pressed against the second wall of the CWG filter; and
a compressible conductive gasket having a gasket inner dimension greater than or equal to the rigid plate inner dimension and configured to slide over the second region of the CWG filter and be compressed between the first wall of the air cavity filter and the rigid plate when the second region of the CWG filter is inserted into the window of the first wall of the air cavity filter.

2. The filter apparatus of claim 1, further comprising incompressible pads configured between the rigid plate and the first wall of the air cavity filter to limit an amount of compression of the compressible conductive gasket.

3.-30. (canceled)

31. The filter apparatus of claim 1, wherein the rigid plate has a rigid plate outer dimension that exceeds the first outer dimension of the first region of the CWG filter.

32. The filter apparatus of claim 1, wherein the compressible conductive gasket has a gasket outer dimension that is less than or equal to an outer dimension of the rigid plate.

33. The filter apparatus of claim 1, wherein the rigid plate is configured with a recess to receive the compressible conductive gasket.

34. The filter apparatus of claim 1, wherein the recess has a depth to enable the compressible conductive gasket to be hidden from view when compressed between the rigid plate and the first wall of the air cavity filter.

35. The filter apparatus of claim 1, further comprising a support base configured to rigidly affix the CWG filter and the air cavity filter when the second region of the CWG filter is inserted into the window.

36. The filter apparatus of claim 1, wherein the CWG filter is configured to be affixed to the support base by at least one clamp that is flexible to allow for thermal expansion of the CWG filter.

37. The filter apparatus of claim 1, wherein the at least one clamp includes a first slot and the support base includes a first hole aligned with the first slot, the at least one clamp being affixable to the support base by inserting an anchoring element into the first hole in the support base through the first slot in the clamp, the first slot enabling adjustment of a position of the clamp in a direction parallel to a direction of the first slot.

38. The filter apparatus of claim 1, wherein the CWG filter has a rectangular cross-section and a broad wall and the at least one clamp is affixable to a surface of the support base that is parallel with the broad wall of the CWG filter.

39. The filter apparatus of claim 1, wherein the CWG filter has a rectangular cross-section and a narrow wall and the at least one clamp is affixable to a surface of the support base that is parallel to the narrow wall of the CWG filter.

40. The filter apparatus of claim 1, further comprising a spring stopper configured to be affixed to the support base and to provide spring-force to the CWG filter in the longitudinal direction of the CWG filter toward the first wall of the air cavity filter to maintain compression of the compressible conductive gasket between the rigid plate and the first wall.

41. The filter apparatus of claim 1, wherein the spring stopper includes a second slot and the support base includes a second hole and the spring stopper is affixable to the support base by inserting an anchoring element into the second hole in the support base through the second slot in the spring stopper, the second slot enabling adjustment of an amount of compression of the compressible conductive gasket.

42. The filter apparatus of claim 1, wherein the rigid plate includes flexible fingers configured to flex under pressure to flatten a curvature of the flexible fingers when compression is applied to the rigid plate.

43. The filter apparatus of claim 1, wherein the rigid plate includes a recess configured to receive the compressible conductive gasket, the compressible conductive gasket having an uncompressed thickness that is greater than a height of the recess.

44. The filter apparatus of claim 1, wherein the rigid plate, is configurable to be soldered to the CWG filter.
